(19) United States
(12) Patent Application Publication
(10) Pub. No.: US 2025/0190828 A1
(43) Pub. Date: Jun. 12, 2025

(54) QUANTUM CIRCUIT DESIGNING APPARATUS AND METHOD

(71) Applicant: Seoul National University R&DB Foundation, Seoul (KR)

(72) Inventors: Namkyoo Park, Seoul (KR); Sunkyu Yu, Seoul (KR)

(73) Assignee: Seoul National University R&DB Foundation, Seoul (KR)

(21) Appl. No.: 18/422,939

(22) Filed: Jan. 25, 2024

(30) Foreign Application Priority Data
May 26, 2023 (KR) 10-2023-0068467

(51) Int. Cl. G06N 10/20

(52) U.S. Cl. CPC G06N 10/20

(57) ABSTRACT

A quantum circuit designing apparatus and method is provided. The quantum circuit designing apparatus includes a processor, and a memory configured to store at least one command to be executed by the processor, wherein the processor removes devices according to importance of each of the devices in a programmable quantum circuit.

### CROSS-REFERENCE TO RELATED APPLICATION

This application claims priority to and the benefit of Korean Patent Application No. 10-2023-0068467, filed on May 26, 2023, the disclosure of which is incorporated herein by reference in its entirety.

### BACKGROUND

### 1. Field of the Invention

The present invention relates to a quantum circuit designing apparatus and method.

### 2. Discussion of Related Art

As representative unitary operation platforms that may be used for universal and reconfigurable purposes, there are programmable photonic circuits, and the concepts corresponding to the programmable photonic circuits are also present in superconducting, ion trap, and semiconductor qubit-based platforms.

In general unitary operation platforms including programmable photonic circuits, the basic strategy for implementing dynamically controllable high-order operators is to decompose a target operator of an n^{th} order unitary group (U(n)) into an n^{th}-order diagonal operator and the n^{th} order unitary operators that perform lower-order unitary operations like SU(2) unit operators in a part of channels. In this case, arbitrary SU(2) unit operators may be implemented using general optical devices such as a beam splitter, a Mach-Zehnder interferometer (MZI), and a phase shifter in the case of an optical system, and arbitrary diagonal operators may also be implemented using a phase shifter.

The characteristics of SU(2) unit operators and diagonal operators may be controlled in arbitrary desired form in real time through modulation of a phase shifter. Accordingly, the entire photonic circuit is a single programmable optical hardware platform and corresponds to universal and reconfigurable unitary operation hardware capable of dynamically implementing arbitrary n^{th} order unitary operators. Through a corresponding platform, it is possible to implement general-purpose quantum gates and quantum computing and deep learning accelerators that require unitary operations.

As techniques for separating a programmable U (n) photonic circuit into lower-order SU(2) unit elements, various types of techniques are present according to the arrangement of each unit optical device, and the techniques correspond to an optimal design problem that a platform with excellent performance is implemented with a structural design. Specifically, by appropriately arranging unit devices, it becomes possible to implement programmable photonic circuits that are resistant to defects that occur during quantum signal processing or consume less power for modulation of phase shifters. In particular, techniques for decomposing high-order unitary operators are commonly applied not only to photonic circuits but also to ion trap, superconducting, and semiconductor qubit-based quantum operations, and thus the optimization problem may be a key task for implementing quantum computing.

As a background art of the present invention, Korean Patent publication No. 10-2023-0028625 published on Mar. 2, 2023 discloses “Multiply device and multiplication method on quantum computer.”

### SUMMARY OF THE INVENTION

The present invention is directed to providing a quantum circuit designing apparatus and method in which, in implementing a high-order unitary operation, devices are removed according to importance thereof to develop a hardware platform for implementing quantum computing and deep learning accelerators, which may be resistant to signal noise or process errors, may achieve high fidelity, and may also be excellent in terms of energy efficiency.

According to an aspect of the present invention, there is provided a quantum circuit designing apparatus including a processor, and a memory configured to store at least one command to be executed by the processor, wherein the processor removes devices according to importance of each of the devices in a programmable quantum circuit.

The device may include a phase shifter.

The processor may derive the importance of the devices to determine a ratio of the devices to be removed and may remove the devices according to the ratio.

The processor may determine the ratio by analyzing noise intensity of the device in a platform.

The processor may implement a unitary operation required for a quantum algorithm circuit or a deep learning accelerator after removing the devices.

The processor may remove devices in a body area among the devices.

According to another aspect of the present invention, a quantum circuit designing method including deriving, by a processor, importance of each of devices in a programmable quantum circuit, and removing, by the processor, the devices according to the importance.

The device may include a phase shifter.

In the removing of the devices according to the importance, the processor may derive the importance of the devices to then determine a ratio of the devices to be removed and remove the devices according to the ratio.

In the removing of the devices according to the importance, the processor may determine the ratio by analyzing noise intensity of the device in a platform.

The quantum circuit designing may further include implementing, by the processor, a unitary operation required for a quantum algorithm circuit or a deep learning accelerator after removing the devices.

In the removing of the devices according to the importance, the processor may remove devices in a body area among the devices.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary diagram of a programmable photonic integrated circuit according to one embodiment of the present invention;

FIG. 2 is a block diagram of a quantum circuit designing apparatus according to one embodiment of the present invention;

FIG. 3 is a flowchart of a quantum circuit designing method according to one embodiment of the present invention;

FIG. 4 is a conceptual view of quantum circuit pruning according to one embodiment of the present invention;

FIG. 5 shows graphs showing that the fidelity of a unitary operation and the learning ability of a deep learning accelerator during a quantum operation according to one embodiment of the present invention are improved as compared with a case in which there is a defect and pruning is not applied;

FIG. 6 shows diagrams showing a physical cause of a “heavy-tailed” characteristic which is a reason why quantum circuit pruning is applicable according to one embodiment of the present invention;

FIG. 7 shows graphs showing that device variables of a unitary photonic circuit have a heavy-tailed distribution;

FIG. 8 shows diagrams showing that, in some cases, quantum circuit pruning is superior as compared with a case in which noise is left without any change;

FIG. 9 shows diagrams illustrating a general-purpose framework for implementing quantum circuit pruning for a general-purpose unitary operation and an effect of applying the quantum circuit pruning based on the same according to one embodiment of the present invention; and

FIG. 10 shows diagrams showing an example of pruning in a photon deep neural network applied to a regression problem according to one embodiment of the present invention.

### DETAILED DESCRIPTION OF EXEMPLARY EMBODIMENTS

Hereinafter, a quantum circuit designing apparatus and method according to one embodiment of the present invention will be described in detail with reference to the accompanying drawings. The drawings are not necessarily to scale and in some instances, proportions may have been exaggerated in order to clearly illustrate features of the embodiments. Further, the terms to be described below are terms defined in consideration of functions in the present invention and thus may vary according to intentions of users or operators or customs. Accordingly, the definitions of such terms should be made based on the content throughout the specification.

Hereinafter, embodiments of the present invention will be described in detail with reference to the accompanying drawings so that those skilled in the art may easily practice the present invention. However, the present invention may be implemented in various forms and is not limited to the embodiments described herein. In the accompanying drawings, portions unrelated to the description will be omitted in order to obviously describe the present invention, and similar reference numerals will be used to describe similar portions throughout the present specification.

Throughout the specification, unless explicitly described to the contrary, the word “comprise” and variations such as “comprises” or “comprising” will be understood to imply the inclusion of stated devices but not the exclusion of any other devices.

Implementations described herein may be implemented in, for example, a method or process, an apparatus, a software program, a data stream, or a signal. Although discussed only in the context of a single form of implementation (e.g., discussed only as a method), implementations of the discussed features may also be implemented in other forms (for example, an apparatus or a program). The apparatus may be implemented in suitable hardware, software, firmware, and the like. A method may be implemented in an apparatus such as a processor, which is generally a computer, a microprocessor, an integrated circuit, a processing device including a programmable logic device, or the like.

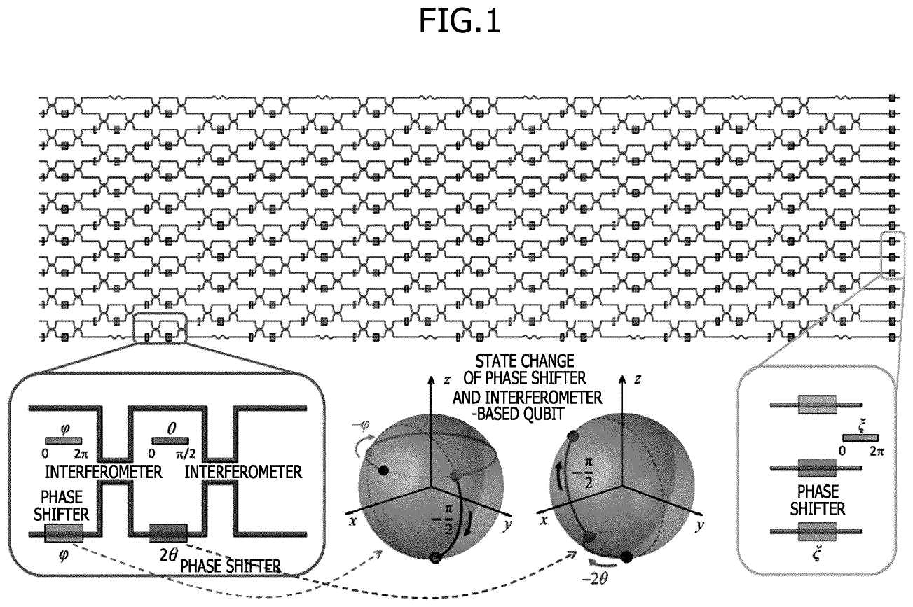

FIG. 1 is an exemplary diagram of a programmable photonic integrated circuit according to one embodiment of the present invention.

Referring to FIG. 1, a quantum circuit to which one embodiment of the present invention may be applied may be a programmable photonic integrated circuit, and a basic unit thereof includes a Mach-Zehnder interferometer and a phase shifter. Each basic unit performs a SU(2) matrix operation between two channels.

The programmable photonic integrated circuit may be a superconducting, ion trap, or semiconductor qubit-based unitary circuit.

Devices 300 are phase shifters for a phase θ and a phase ϕ, respectively. Two phases θ and ϕ each represent an amount of phase change of light that occurs when the light passes through each device and are determined by the product of a change in refractive index of a medium in the device, a wavenumber of the light, and a length of the device. A rotation matrix operation is performed on a Bloch sphere through two phase shifters, and a phase shifter for a diagonal matrix is shown in a right orange box. The phase θ and the phase ϕ of each basic unit may be controlled in the same way, which makes it possible to implement arbitrary unitary matrix operation on light. In addition, the sizes of the phase θ and the phase ϕ are proportional to energy consumption required to change a refractive index of light and determine a change in Bloch sphere indicated by each SU(2) unit operator, thereby indicating importance of each device.

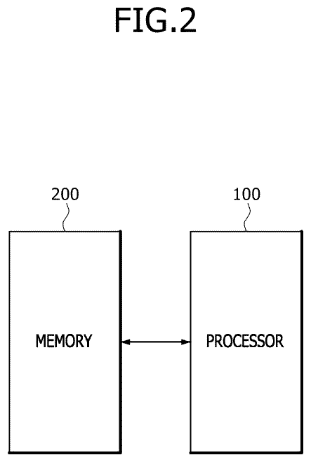

FIG. 2 is a block diagram of a quantum circuit designing apparatus according to one embodiment of the present invention.

Referring to FIG. 2, the quantum circuit designing apparatus according to one embodiment of the present invention includes a memory 200 and a processor 100.

The processor 100 removes devices 300 according to the importance of each of the devices 300 in a programmable quantum circuit.

That is, when a universal unitary operation is implemented, by using that a statistical distribution of phase shifters, which are one of core components, is a heavy-tailed distribution, the processor 100 removes the devices 300 of the phase shifters which are relatively less important, that is, statistically, the devices 300 of the phase shifters in a body area among all phase shifters.

The memory 200 stores at least one command executed by the processor 100. The command may be for deriving the importance of the devices 300, determining a ratio of the devices 300 to be removed, first removing the devices 300 with relatively low importance according to the determined ratio, and then implementing a unitary operation required for an algorithm circuit or a deep learning accelerator using a quantum circuit including the remaining devices 300.

The memory 200 may be a volatile or non-volatile storage medium, for example, a read-only memory (ROM) or a random access memory (RAM), or an electronic or quantum memristor.

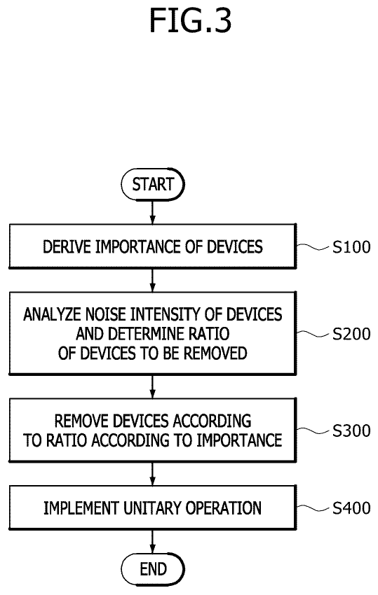

A quantum circuit designing method according to one embodiment of the present invention will be described with reference to FIG. 3.

FIG. 3 is a flowchart of a quantum circuit designing method according to one embodiment of the present invention.

Referring to FIG. 3, first, a processor 100 derives importance of each of devices 300 (S100).

Next, the processor 100 determines a ratio of the devices 300 to be removed (S200). In this case, the processor 100 may analyze the noise intensity of the devices 300 in a platform and may determine the ratio of the devices 300 to be removed.

As the ratio of the devices 300 to be removed is determined, the processor 100 first removes the devices 300 with relatively low importance according to the above ratio (S300).

The devices 300 with relatively low importance may be devices 300 in a body area, but are not particularly limited.

The processor 100 implements a unitary operation required for a quantum algorithm circuit or a deep learning accelerator by using quantum circuits left after the devices 300 with relatively low importance are removed as described above (S400).

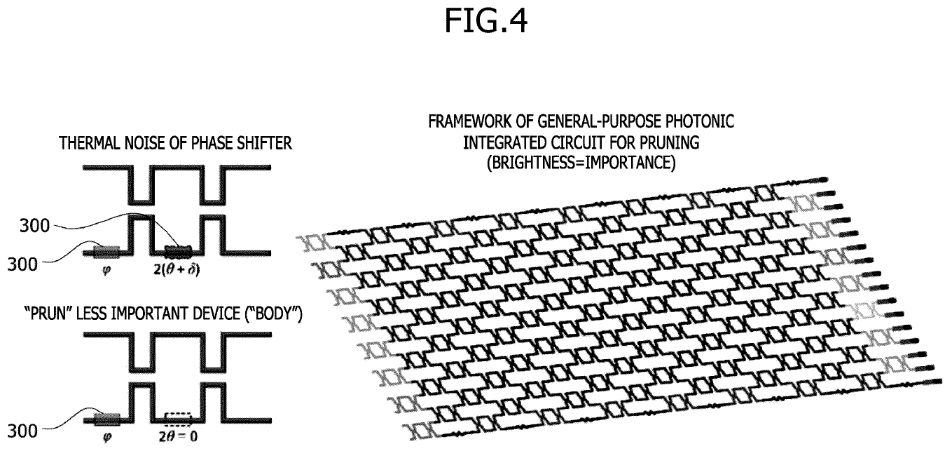

FIG. 4 is a conceptual view of quantum circuit pruning according to one embodiment of the present invention.

Referring to FIG. 4, when an error or defect occurs in a phase shift due to thermal noise or process errors in phase shifters of a circuit, phase shifters with relatively low importance among the phase shifters, that is, phase shifters, which play a relatively less important role, are not installed during a design to prevent the occurrence of an error or defect.

In this case, the fidelity of the circuit decreases because the design differs from an ideal design, but a degree of decrease is less than that of a defect of a certain level or more, and as a result, it is possible to construct an overall circuit that is resistant to defects.

FIG. 4 illustrates a framework of a photon-based quantum circuit in which the importance of each device 300, which is derived from a combination of random Haar Matrices which are standards when quantum circuit pruning is applied, is expressed by brightness.

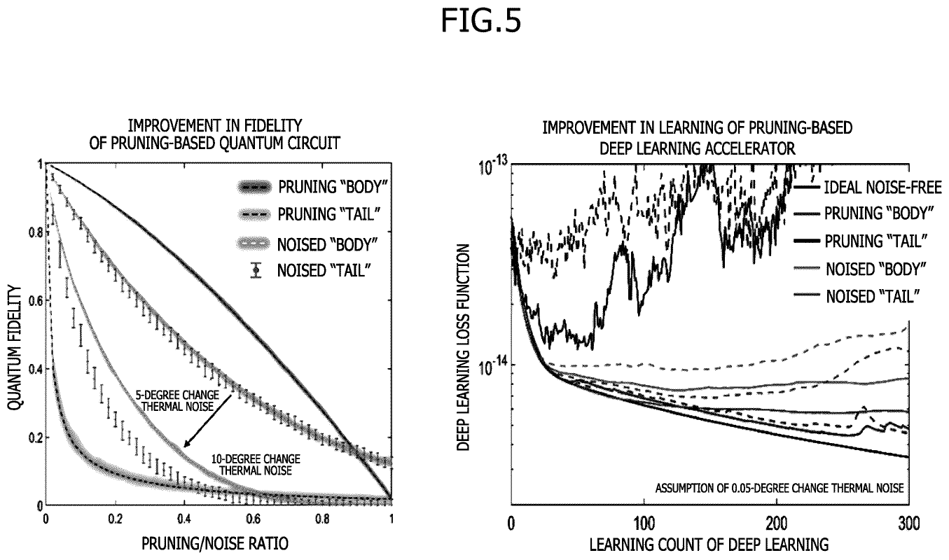

FIG. 5 shows graphs showing that the fidelity of a unitary operation and the learning ability of a deep learning accelerator during a quantum operation according to one embodiment of the present invention are improved as compared with a case in which there is a defect and pruning is not applied.

Referring to FIG. 5, it can be seen that the fidelity of the unitary operation and the learning ability and operation fidelity of the deep learning accelerator during the quantum operation are improved as compared which pruning is not applied.

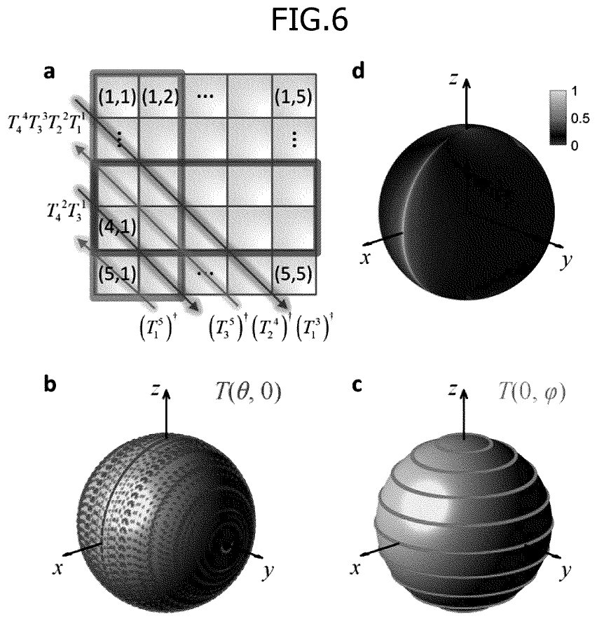

FIG. 6 shows diagrams illustrating a physical cause of a “heavy-tailed” characteristic which is a reason why quantum circuit pruning is applicable according to one embodiment of the present invention.

Referring to FIG. 6, when an arbitrary value is given to a phase shifter for a phase θ of two phase shifters constituting a unit element, a distribution on a Bloch sphere becomes non-uniform. In addition, FIG. 6 illustrates that when a SU(2) matrix operation corresponding to unitary components is implemented, as the number of SU(2) matrix operations applied to each component changes, a distribution of the phase θ may be non-uniform.

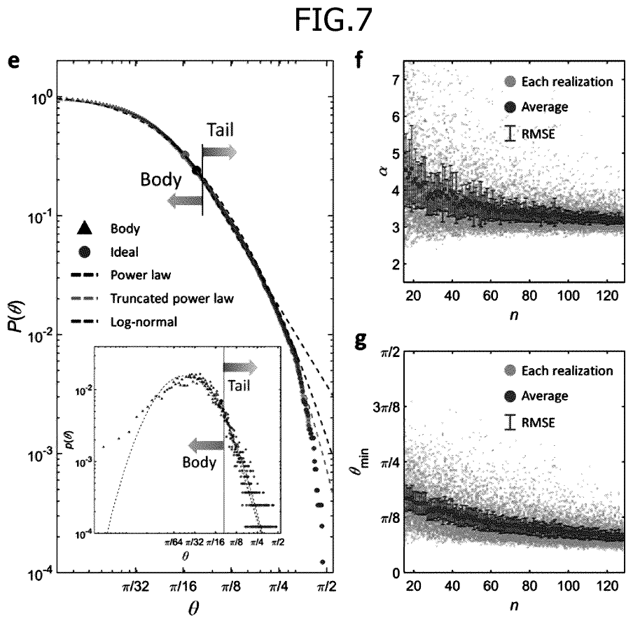

FIG. 7 shows graphs showing that device variables of a unitary photonic circuit have a heavy-tailed distribution.

FIG. 7E shows a heavy-tailed distribution of a phase θ. An inserted graph shows results of fitting using a probability distribution function (PDF) and a heavy-tailed distribution thereof.

A body and a tail were separated at P(θ)=0.20 with reference to a Pareto principle.

Red, orange, and blue dashed lines indicate fittings using a power law, a power law with exponential cut-off, and a log-normal distribution model, respectively.

The red and orange circles indicate lower limits, that is, ranges of tails, of function fittings for the power law and the power law with the exponential cut-off, respectively.

FIGS. 7F and 7G show a change in power law estimation variable according to a change in n value, that is, power law variables α(f) and θₘᵢₙ(g). Each blue dot indicates a single realization, and an orange marker and an error bar indicate a mean and a root mean square error (RMSE) of n 100 random realizations, respectively.

As shown in FIG. 2 above, since a phase θ corresponds to the importance of each device, the importance of each device constituting an arbitrary unitary operation has a heavy-tailed distribution, and as a size of the phase θ designed according to a given unitary operation becomes smaller, a device corresponds to a less important device that is advantageous to be removed.

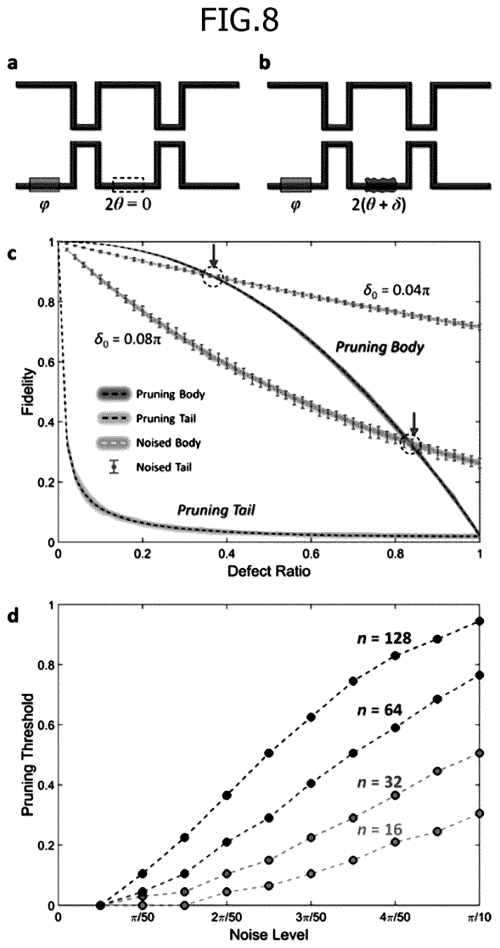

FIG. 8 shows diagrams showing that, in some cases, quantum circuit pruning is superior as compared with a case in which noise is left without any change.

FIG. 8A shows a concept of quantum circuit pruning in a programmable optical circuit. When there is a possibility that a phase shifter for a phase 2θ causes noise, the phase shifter for the phase 2θ is replaced by a general waveguide that preserves symmetry in a Mach-Zehnder modulator. In this case, a defect can be eliminated because there is no modulator that may potentially cause thermal noise.

FIG. 8B shows a device 300 in which defects are mixed. Due to a defect such as a change in refractive index due to heat or a process error, the phase converter for the phase 2θ is distorted into a phase converter for a phase 2(0+8).

FIG. 8C shows a comparison between fidelities of U₁₂₈ optical circuits in different groups. A pruning body (red line), a pruning tail (blue line), a noised body (orange line), and a noised tail (green error bar) are shown. Thicknesses of a color line and an error bar each indicate a range of fidelity between a maximum value and a minimum value. A red arrow indicates a quantum circuit pruning threshold for each case. The noised body and the noised tail are shown for two groups for δ₀=0.04π and δ₀=0.08π corresponding to a temperature change of 2 K to 4 K.

FIG. 8D shows a quantum circuit pruning threshold for a noise level 80 according to a degree of various unitary operators. In FIGS. 8C and 8D, 100 random Un realizations for each n and defect rate are analyzed.

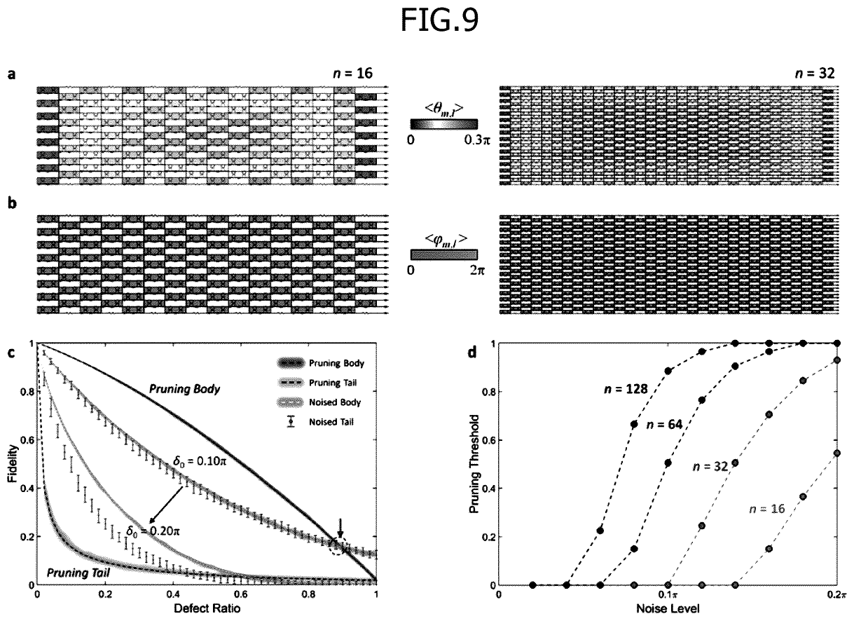

FIG. 9 shows diagrams illustrating a general-purpose framework for implementing quantum circuit pruning for a general-purpose unitary operation and an effect of applying the quantum circuit pruning based on the same according to one embodiment of the present invention.

FIGS. 9A and 9B show an average of <θ_{m,l}> (in FIG. 9A) and an average of <φ_{m,l}> (in FIG. 9B) for 100 Un realizations when n=16 and n=32. In order to increase visibility, an upper limit of a color map of FIG. 9A was set to 0.3π.

FIG. 9C shows a comparison between fidelities of different groups of U₁₂₈ optical circuits, that is, a pruning body (red line), a pruning tail (blue line), a noised body (orange line), and a noised tail (green error bar). Thicknesses of the colored lines and the error bar indicate a range of maximum fidelity and minimum fidelity. A red arrow indicates each pruning threshold. Two groups with a noised body and a nosed tail are shown for the cases of δ₀=0.04π and δ₀=0.08π corresponding to a temperature change in FIGS. 4 to 6.

FIG. 9D shows a quantum circuit pruning threshold of δ₀ according to a noise level for different unitary orders (n). In FIGS. 9C and 9D, 100 random Un realizations per n and defect ratio were analyzed.

The noise intensity of a device is determined by a specific implementation method of a phase shifter. Representative examples include thermal noise or a process error. According to known average noise of a used phase shifter, the fidelity according to a ratio (defect ratio) of devices in which noise is generated as shown in FIG. 9C, is calculated by applying a theory such as an optical transmission matrix method, and then when the calculated fidelity is compared with that of a case in which a pruning body at the same ratio is applied, a pruning threshold is indicated when the fidelities are the same. Quantum circuit pruning is a technique that removes devices in order of devices with less importance by a ratio corresponding to a calculated pruning threshold.

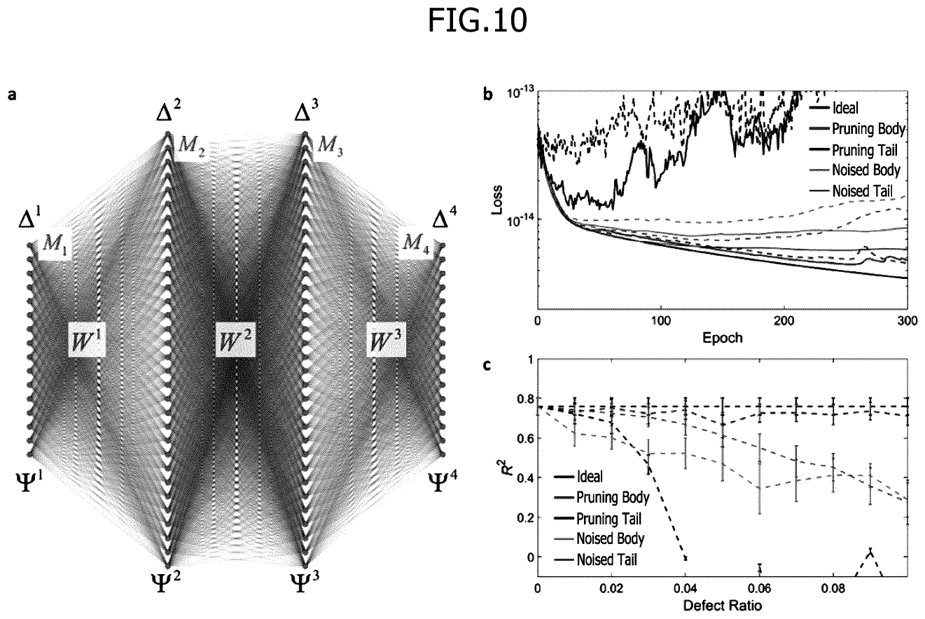

FIG. 10 shows diagrams showing an example of pruning in a photon deep neural network applied to a regression problem according to one embodiment of the present invention.

FIG. 10A shows a structure of a deep neural network for analyzing a pruning effect. Mₚ (p=1, 2, 3, and 4) denotes the number of neurons in each layer, wherein M₁=M₄=16, and M₂=M₃=32. Ψ^{p} and Δ^{p} are a signal and an error column vector in each layer and represent aₖ^{p} and δₖ^{p} which are a signal and an error in a k^{th} neuron (k=1, 2, . . . , and Mₚ) of each layer. WP is a weight matrix between a p^{th} layer and a (p+1)^{th} layer.

FIGS. 10B and 10C show a learning curve (in FIG. 10B) and R-squared accuracy (in FIG. 10C) which are estimated with a test dataset. Colors of lines indicate different groups of unitary optical circuits, and s pruning body (red), a pruning tail (blue), a nosed body (orange), and a nosed tail (green error bar) are shown. The noised body and the noised tail are shown for a case of δ₀=0.001π. A solid line and a dotted line in FIG. 10B indicate defect ratios of 5% (2σ/n(n−1)=0.05) and 10% (2σ/n(n−1)=0.10), respectively. In FIG. 10C, a dotted line and an error bar indicate a mean value and half of a standard deviation of a test dataset accuracy of 1,000 examples. The disconnection of the blue dotted line in FIG. 10C indicates a learning failure due to network parameter divergence.

As such, in a quantum circuit designing apparatus and method according to one embodiment of the present invention, in implementing a unitary matrix operation required for a general-purpose quantum operation or a deep learning accelerator, components are classified according to importance, and quantum circuit pruning of excluding less important devices are applied, thereby obtaining an effect of achieving a higher level of fidelity and energy efficiency with respect to thermal noise or a process error of a certain level or more.

For example, in an example of implementing a light-based 64′64 or 8-qubit system unitary matrix operation using a programmable photonic circuit made of silicon, when it is assumed that a temperature of a circuit changes by about 5 degrees due to heat generation, even when less than half of devices 300 are removed, the quantum circuit designing apparatus and method according to one embodiment of the present invention allows to higher fidelity to be obtained as compared with a related art. In addition, in a quantum circuit designing apparatus and method according to one embodiment of the present invention allows higher fidelity and energy efficiency to be secured when a quantum computer and large-capacity deep learning accelerator hardware are implemented at a noisy intermediate-scale quantum (NISQ) level or an NISQ level or more using light.

In a quantum circuit designing apparatus and method according to an aspect of the present invention, in implementing a unitary matrix operation required for a general-purpose quantum operation or a deep learning accelerator, components are classified according to importance, and quantum circuit pruning of excluding less important devices are applied, thereby achieving a higher level of fidelity and energy efficiency with respect to a certain level or more of thermal noise or a process error.

The present invention has been described with reference to embodiments shown in the drawings, but this is merely illustrative, and those skilled in the art will understand that various modifications and other equivalent embodiments are possible therefrom. Therefore, the true technical protection scope of the present invention should be defined by the appended claims.

What is claimed is:

1. A quantum circuit designing apparatus comprising:
a processor; and
a memory configured to store at least one command to be executed by the processor,
wherein the processor removes devices according to importance of each of the devices in a programmable quantum circuit.

2. The quantum circuit designing apparatus of claim 1, wherein the device includes a phase shifter.

3. The quantum circuit designing apparatus of claim 1, wherein the processor derives the importance of the devices to determine a ratio of the devices to be removed and removes the devices according to the ratio.

4. The quantum circuit designing apparatus of claim 3, wherein the processor determines the ratio by analyzing noise intensity of the device in a platform.

5. The quantum circuit designing apparatus of claim 1, wherein the processor implements a unitary operation required for a quantum algorithm circuit or a deep learning accelerator after removing the devices.

6. The quantum circuit designing apparatus of claim 1, wherein the processor removes devices in a body area among the devices.

7. A quantum circuit designing method comprising:
deriving, by a processor, importance of each of devices in a programmable quantum circuit; and
removing, by the processor, the devices according to the importance.

8. The quantum circuit designing method of claim 7, wherein the device includes a phase shifter.

9. The quantum circuit designing method of claim 7, wherein in the removing of the devices according to the importance, the processor derives the importance of the devices to then determine a ratio of the devices to be removed and removes the devices according to the ratio.

10. The quantum circuit designing method of claim 9, wherein in the removing of the devices according to the importance, the processor determines the ratio by analyzing noise intensity of the device in a platform.

11. The quantum circuit designing method of claim 7, further comprising implementing, by the processor, a unitary operation required for a quantum algorithm circuit or a deep learning accelerator after removing the devices.

12. The quantum circuit designing method of claim 7, wherein in the removing of the devices according to the importance, the processor removes devices in a body area among the devices.
